(19) United States
(12) Patent Application Publication
(10) Pub. No.: US 2007/0000595 A1
(43) Pub. Date: Jan. 4, 2007

(54) Adhesive substrate and method for using

(75) Inventor: Edward R. Prack, Phoenix, AZ (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 11/171,956

(22) Filed: Jun. 29, 2005

(51) Int. Cl. B32B 38/00; B32B 37/12; B32B 38/10; H01L 21/20; H01L 21/30; H01L 21/31; B32B 7/12

(52) U.S. Cl. 156/154; 156/247; 156/280; 156/538; 438/459; 438/584; 438/758; 438/759; 438/760; 428/343; 428/355 R

(57) ABSTRACT

A system, apparatus and method of using an adhesive substrate capable of maintaining adhesion between a carrier and a work piece during a thinning process and then withstanding processing temperatures equal to or in excess of 160 degrees Celsius and with subsequent removal of the carrier and the adhesive substrate without solvent are described herein.

### FIELD OF THE INVENTION

Embodiments of the present invention relate generally to substrates with adhesive layers. More specifically, the present invention is related to the formation and use of adhesive substrates that can be peeled off the work piece upon completion of processing that may include high temperatures.

### BACKGROUND

As integrated circuit technology continues to advance, some work pieces, such as semiconductor wafers, are expected to be subjected to ever increasingly extreme environmental conditions during processing and assembly. Various stages of semiconductor fabrication and processing are expected to create environmental conditions where temperatures will exceed certain thresholds. For example, backside metallization of a wafer is expected to expose the wafer and any carriers that may be used to temperatures that exceed 130 degrees Celsius. During wafer assembly reflow, the temperature is expected to easily exceed 250 degrees Celsius; and for wafer level FAB processing (including oxide deposition and polyimide deposition), the temperature is expected to exceed 350 degrees Celsius.

### BRIEF DESCRIPTION OF THE DRAWINGS

The present invention will be described by way of exemplary embodiments, but not limitations, illustrated in the accompanying drawings in which like references denote similar elements, and in which:

FIG. 1a illustrates a cross-sectional representation of an adhesive substrate with one adhesive layer, in accordance with one embodiment of the invention;

FIG. 1b illustrates a cross-sectional representation of an adhesive substrate with two adhesive layers, in accordance with one embodiment of the invention;

FIGS. 2a-2h are cross-sectional views of a work piece using the adhesive substrate during various stages of fabrication, in accordance with an embodiment of the methods of the present invention;

FIG. 3 illustrates an exemplary flow diagram of a method of fabrication of a work piece using an adhesive substrate, in accordance with one embodiment of the invention; and

FIG. 4 is a block diagram of a system incorporating a laminator used in affixing the adhesive substrate, in accordance with one embodiment of the invention

### DETAILED DESCRIPTION

In the following detailed description, reference is made to the accompanying drawings which form a part hereof wherein like numerals designate like parts throughout, and in which are shown, by way of illustration, specific embodiments in which the invention may be practiced. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

The following description may include terms such as “on”, “onto”, “on top”, “underneath”, “underlying”, “downward”, “lateral”, and the like, are used for descriptive purposes only and are not to be construed as limiting. That is, these terms are terms that are relative only to a point of reference and are not meant to be interpreted as limitations, but are instead included in the following description to facilitate understanding of the various aspects of the invention.

The phrase “in one embodiment” is used repeatedly. The phrase generally does not refer to the same embodiment; however, it may sometimes refer to the same embodiment.

The terms “comprising”, “having” and “including” are synonymous, unless the context dictates otherwise.

Further, various operations will be described as multiple discrete operations, in turn, in a manner that is most helpful in understanding the present invention; however, the order of description should not be construed as to imply that these operations are necessarily order dependent. In particular, these operations need not be performed in the order of presentation. In addition, one or more of the operations may be eliminated while other operations may be added in different embodiments of the invention.

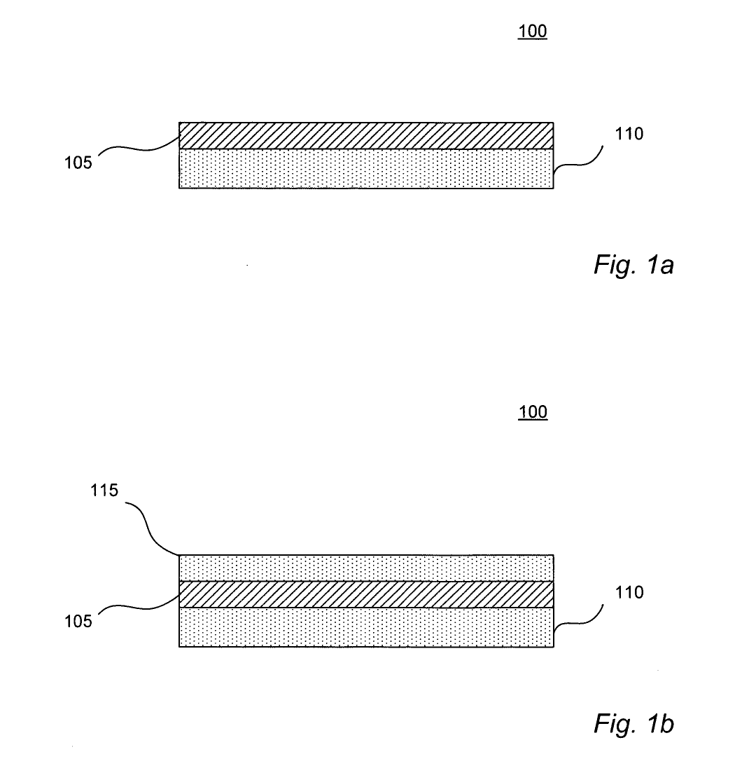

FIG. 1a illustrates a cross sectional representation of an adhesive substrate 100 having a flexible film 105 and adhesive layer 110 in accordance with one embodiment. For the embodiment, a first adhesive layer 110 is on a first side of the flexible film. To illustrate for purposes of ease of discussion, only one exemplary layer is illustrated for flexible film 105; however, this is not to be construed as limiting and the flexible film 105 may comprise multiple layers. For the embodiments, adhesive substrate 100 is configured to withstand processing temperatures in excess of about 130 degrees Celsius. For some embodiments, to assist in withstanding the temperatures in excess of about 130 degrees Celsius, the flexible film 105 may have a glass transition temperature greater than about 130 degrees Celsius. For yet another embodiment, the flexible film has a glass transition temperature greater than 160 degrees Celsius. Alternately, in an embodiment, the flexible film has a glass transition temperature greater than 250 degrees Celsius. In another embodiment, the flexible film 105 has a glass transition temperature greater than 350 degrees Celsius. In other embodiments, the flexible film 105 has a glass transition temperature greater than 400 degrees Celsius.

FIG. 1b illustrates a cross sectional representation of the adhesive substrate 100 having a second adhesive layer 115, in accordance with another embodiment. For this embodiment, a first adhesive layer 110 of the two adhesive layers is on a first side of the flexible film while a second adhesive layer 115 of the two adhesive layers is on a second side of the flexible film.

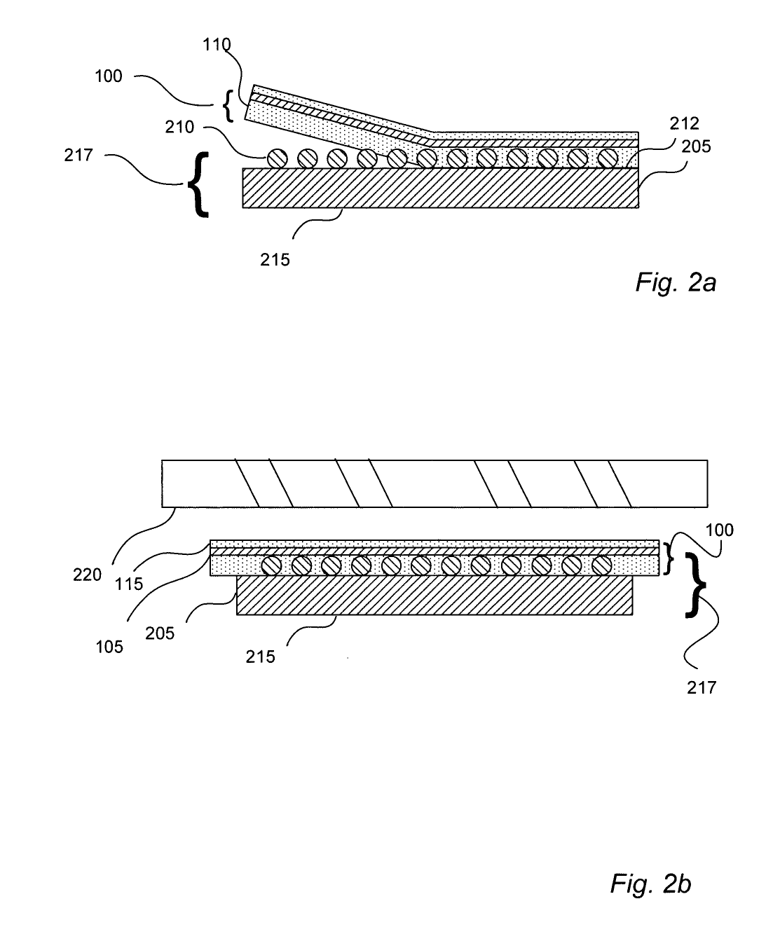

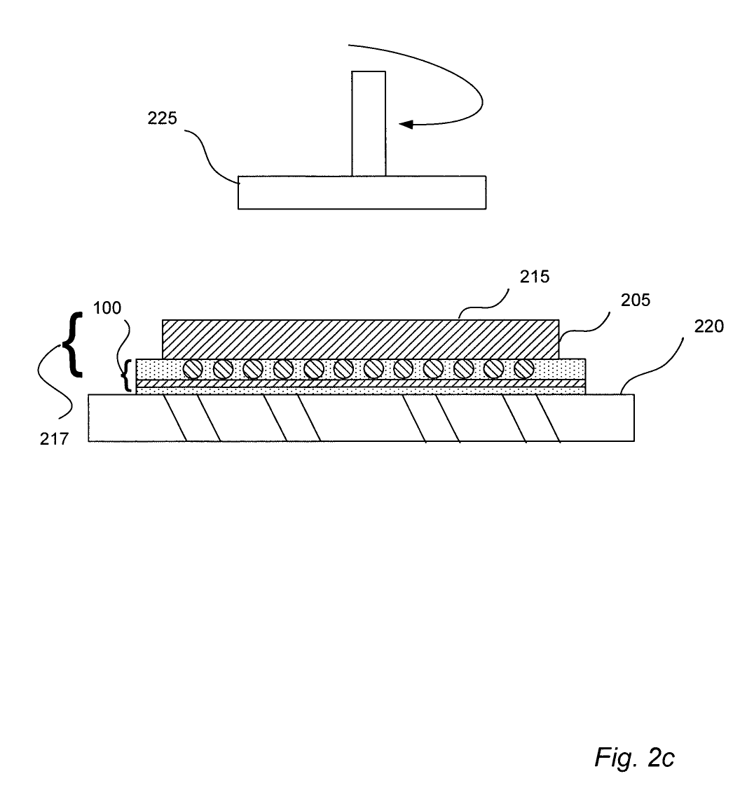

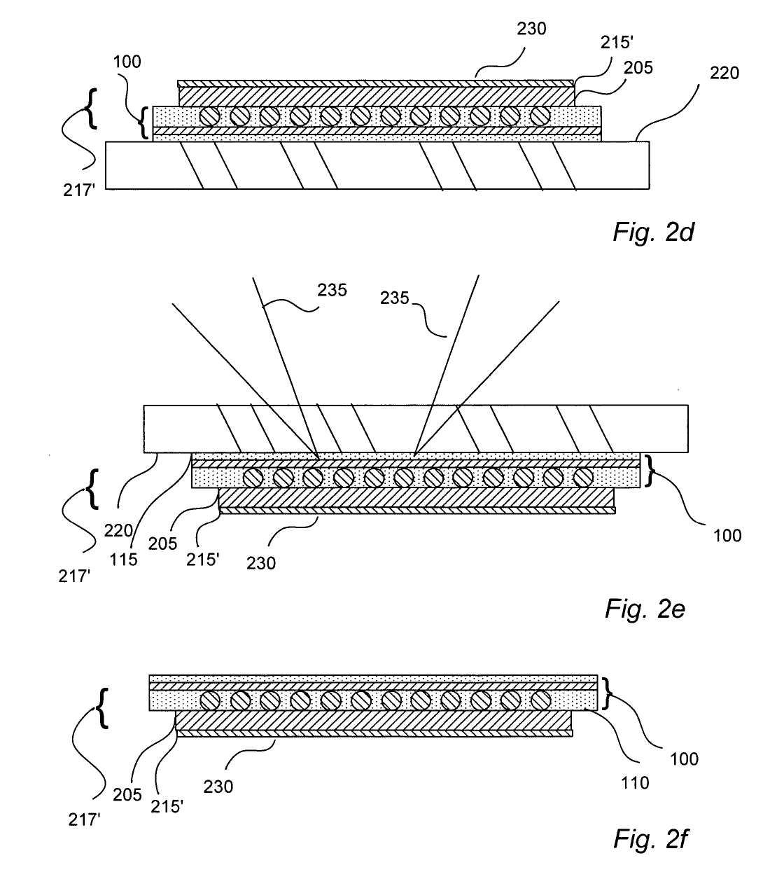

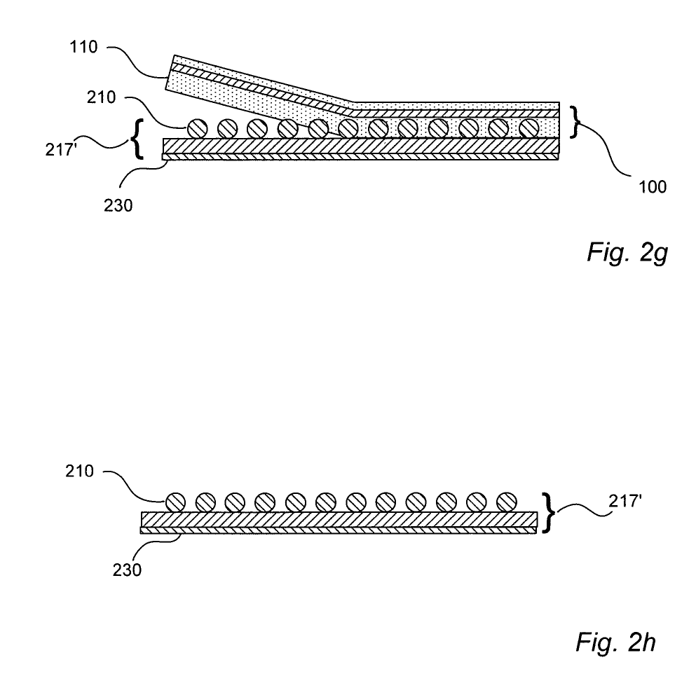

FIG. 2a illustrates a cross sectional representation of adhesive substrate 100 being laminated onto a work piece 217 according to an embodiment. Work piece 217 may comprise a wafer 205 having first side 212 and a second side 215. In some embodiments work piece 217 the second side 215 may be referred to as the “backside” while the first side 212 may be referred to as the “device side”. Additionally, for some embodiments, the device side 212 may have structures 210. Those structures 210 may include, for example, interconnects, 210. As indicated above, adhesive substrate 100 (which may also be referred to as tape) may be laminated onto work piece 217. First adhesive layer 110, for various embodiments, may have a thickness equal to or greater than structures on the first side of the work piece.

FIG. 2b illustrates a cross sectional representation of the adhesive substrate 100 laminated on to the work piece 217 according to an embodiment. In another embodiment a carrier 220 may also be affixed by the adhesive substrate 100 to the work piece 217 if the work piece 217 requires additional support. To assist in alignment of the work piece 217, for some embodiments, the flexible film 105 may have an optical clarity sufficient to allow fiducial markings (not shown) to be observed through the film 105. For another embodiment, the flexible film has an optical clarity of more than 90% T in a visible range. Further, for an embodiment, carrier 220 may also have an optical clarity sufficient to allow fiducial markings (not shown) to be observed through the carrier 220.

FIG. 2c illustrates a cross sectional representation the work piece 217 affixed to carrier 220 with the substrate 100 according to an embodiment. Thinning of the backside 215 of the work piece may be done thorough any number of means, including a backgrinding operation represented by grinding pad 225, in accordance with various embodiments. However, other thinning operations including chemical, may be performed. The adhesive substrate 100 maintains adhesion between the work piece 217 and the carrier 220 during the thinning operation. According to various embodiments, the sheer and tensile strength of the flexible film 105 and the first and second adhesives 110 and 115 should be relatively high to prevent failure of adhesion between the carrier 220 and the work piece 217. For the embodiments where only the first adhesive layer 110 is utilized and the carrier 220 is not utilized, the adhesive substrate 100 would maintain adhesion between the flexible film 105 and the work piece 217 during the thinning operation.

Young's modulus for the flexible film 105 may be greater than 1 GPa for various embodiments. The flexible film 105 may have a Young's modulus between approximately 1.5 GPa and approximately 2.3 GPa. The flexible film may have a Young's modulus of approximately 1.9 GPa.

The flexible film 105 may have a tensile strength between approximately 40 MPa and approximately 60 Mpa for an embodiment. For various embodiments, the tensile strength should be greater then a peel force. For an embodiment, the flexible film 105 may have an approximate tensile strength between approximately 40 MPa and 60 MPa. In another embodiment, the flexible film 105 may have an approximate tensile strength of 50 MPa.

Young's modulus for the first layer 110 in various embodiments may be in a range of approximately 100 to 500 MPa. If, according to an embodiment, the substrate 100 has the second adhesive layer 115, the second adhesive layer 115 may have a Young's modulus in the same approximate range.

For various embodiments, the first adhesive layer 110 may have a thermogravimetric analyzer (TGA) temperature for less than about a 5% weight loss in a range of about 130 to about 500 degrees Celsius. While in other embodiments, the first adhesive layer 110 may have less than about 5% weight loss as determined by thermal gravimetric analysis (TGA) in a temperature range of about 130 to about 400 degrees Celsius. While in other embodiments, the first layer may less than about 5% weight loss as determined by TGA in a temperature range of about 250 to about 400 degrees Celsius. Additionally, for an embodiment, the first adhesive layer 110 may have less than about a 5% weight loss as determined by TGA at about 400 degrees Celsius. For those embodiments where the substrate 100 has the second adhesive layer 115, the second adhesive layer 115 may have similar TGA weight loss measurements as described above for the first adhesive layer 110.

In an embodiment, the flexible film 105 may have a glass transition temperature in excess of approximately 130 degrees Celsius. In another embodiment, the flexible film 105 may have a glass transition temperature in excess of approximately 160 degrees Celsius. For other embodiments, the flexible film 105 may have a glass transition temperature in excess of approximately 250 degrees Celsius. In yet other embodiments, the flexible film 105 may have a glass transition temperature in excess of approximately 350 degrees Celsius. In an embodiment, the flexible film 105 may have a glass transition temperature in excess of approximately 400 degrees Celsius.

FIG. 2d illustrates a cross sectional representation of the thinned work piece 217′ after some additional post-thinning operation has been performed, according to an embodiment. In some embodiments, the additional post-thinning operation may expose the thinned-work piece 217′ and the adhesive layer 110 to temperatures in excess of 130 degrees Celsius. Various examples of those processes include, e.g., backside metallization 230 of the thinned wafer 215′ where temperatures can exceed 160 degrees Celsius, wafer assembly reflow, where temperatures may easily exceed 250 degrees Celsius; and wafer level processing (including oxide deposition and polyimide deposition) where temperatures may exceed 350 degrees Celsius. For those embodiments where the substrate 100 further comprises the second adhesive layer 115, the second adhesive layer 115 may also exposed to the same temperatures as the first adhesive layer 110

FIG. 2e illustrates a cross sectional representation of the post-processed, thinned work piece 217′ affixed to carrier 220 with the substrate 100, while the seond adhesive layer 115 is being exposed to electromagnetic radiation 235, according to an embodiment. In various embodiments, the adhesive may be designed so that the adhesive strength of the second adhesive layer 115 may be reduced or eliminated by exposure to certain electromagnetic radiation 235. For some embodiments, the electromagnetic radiation 235 may be in the form of ultra-violet (UV) radiation or thermal radiation. When using UV radiation, the carrier 220 should be nearly UV transparent. When using thermal radiation, care should be taken to not generate too much heat and damage the thinned-work piece 217′.

FIG. 2f illustrates a cross sectional representation of the post-processed, thinned work piece 217′ with the substrate 100 once carrier 220 has been removed without use of a solvent, according to an embodiment. While it is not necessary to eliminate the adhesive strength of the second adhesive layer 115, for some embodiments, the strength should be sufficiently low to enable removal of the carrier without removal of the adhesive substrate 100 from the thinned-work piece 217′.

FIG. 2g illustrates a cross sectional representation of the post-processed, thinned work piece 217′ with the substrate 100 being peeled off of the post-processed, thinned work piece 217′ without use of a solvent according to an embodiment. For those embodiments where the carrier 220 has been utilized, the peeling may be accomplished after the carrier 220 has been removed. In contrast to the discussion for FIG. 2f, for other embodiments, the second adhesive for the first adhesive layer 110 may be designed so that the adhesive strength of the first layer 110 may be reduced or eliminated by exposure to the electromagnetic radiation 234. Then, for an embodiment, the adhesive substrate may be removed from the carrier 220 after peeling the carrier 220 with the adhesive substrate 100 from the thinned-work piece 217′.

Regardless of the method used to reduce the adhesive strength of the first adhesive layer 110 (if any), for various embodiments, the force required to peel the first adhesive layer 110 from a polyimide surface may be designed to be less than, or approximately 1 g/mm^{2 during} 180-degree peel; the force required to peel the first adhesive layer 110 from a metal pad or bump material may be designed to be less than, or approximately, 15 N/in during a 180-degree peel; and the force required to peel the first adhesive layer 110 from a SIO₂ may be designed to be less than, or approximately, 0.3 N/in during a 180-degree peel.

FIG. 2h illustrates a cross sectional representation of the post-processed, thinned work piece 217′, after adhesive substrate 100 and carrier 220 have been removed.

For embodiments of the flexible film 105 materials for various embodiments for the flexible film 105 may include, but are not limited to, products such as those sold under the trademarks “Appear™ 3000”, a polynorborene based product; “Sumilite® FS-1101”, a polyether-ether-ketone (PEEK) based product; “Sumilite® FS-1200”, a polysulfone (PSF) based product; “Sumilite® FS-1300”, a polyethersulfone (PES) base product; “Sumilite® FS-1400”, a polyetherimide (PEI) based product; “Sumilite® FS-1700”, a Cyclo-Olefin-Polymer (COP) based product; and “Sumilite® FST-5300”, a polyethersulfone (PES) based product, distributed by Promerus LLC.

Additionally polyimide monomer sets such as PMDA_ODA and BPDA_ODA may be obtained from various suppliers. “APICAL® Type AV” a polyimide based product distributed by Kaneka High-Tech Materials, Inc.; “UPILEX-S®”, a polyimide based product distributed by UBE America, Inc.; “R/Flex®” 3000 series LCP films, a aromatic crystal based product distributed by Rogers Corporation; and “Kapton®” and “Oasis®” films, polyimide based products such as PMDA-ODA monomer sets distributed by DuPont High Performance Films. Other suitable products may be used to practice the embodiments described herein for use as the flexible film 105. such as DuPont

Suitable materials for various embodiments for the first and/or second adhesive layers 110 and 115 described herein may include, but are not limited to, materials such as those sold under the trademarks “Dow Corning® Q1-4010” and “Dow Corning® WL-5150”, silicon elastomer based products distributed by the Dow Corning Corporation; “Unity™ 400”, a polycyclic olefin polymer, distributed by Promerus LLC; “EXP-248™” distributed by 3M Corporation; and QPAC® 25, a poly(ethylene carbonate), and QPAC® 40, a poly(propylene carbonate), distributed by Empower Materials, a subsidiary of Axess Corporation. Other suitable products may be configured to practice the embodiments described herein for use as the adhesive layers 110 and 115. For an embodiment, the adhesive layer 110 may comprise different materials from those that constitute adhesive layer 115.

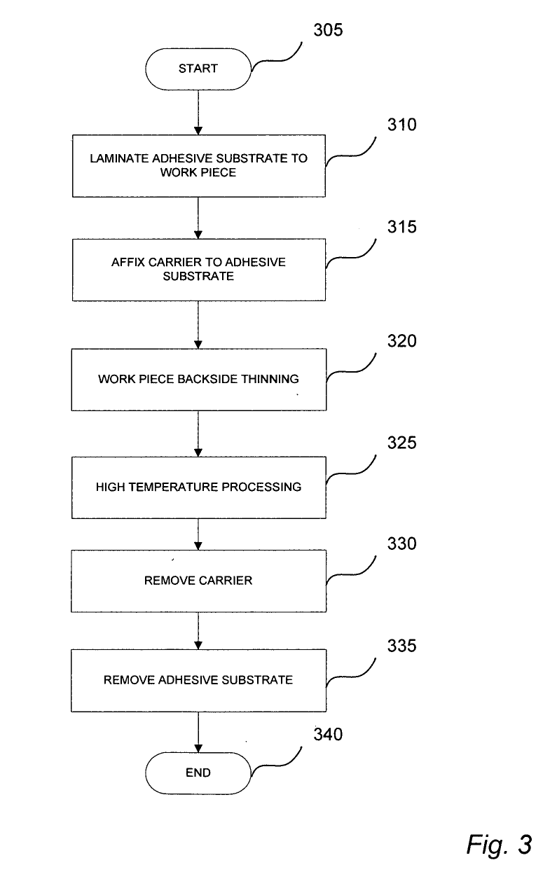

FIG. 3 illustrates a flow diagram of a suitable method of a fabrication process using adhesive substrate 100 as illustrated in FIG. 1, in accordance with one embodiment of the invention. At 305, the process begins. At process point 310, for the embodiments, a first side of the adhesive substrate may be laminated on to a first side of a work piece as illustrated in FIG. 2a.

Next, for some embodiments, at 315, a carrier for transporting and/or supporting the work piece may be affixed to a second side of the adhesive substrate as illustrated in FIG. 2b.

Next, for various embodiments, at 320, the work piece may be processed. The back side (a second side) of the work piece, in accordance with the embodiments, may be thinned. Thinning of the backside of the work piece may be done through any number of means including a backgrinding operation, in accordance with various embodiments as illustrated in FIG. 2c. However, other thinning operations, known to those of ordinary skill in the art, including chemical, may be performed. The adhesive substrate maintains adhesion between the work piece and the carrier during the thinning operation. According to various embodiments, the sheer and tensile strength of the flexible film and the first adhesive and should be relatively high to prevent failure of adhesion between the flexible film and the work piece. For other embodiments, if a carrier is used, the sheer and tensile strength of the flexible film and the first and second adhesives should be relatively high to prevent failure of adhesion between the carrier and the work piece.

Next, for some embodiments, at 325, the thinned work piece may be exposed to additional processing. During this additional processing the work piece assembly, including the adhesive substrate, may be exposed to a processing temperature in excess of approximately 130 degrees Celsius. For some embodiments, the additional processing of the thinned work piece may include depositing metal, depositing a thin dielectric thin film, electroplating, oxide deposition, and polymer deposition on the second side of the work piece assembly. In other embodiments, the additional processing of the thinned work piece may include high temperature solder reflow of the work piece assembly. These are merely exemplary of a type of processing that may expose the work piece assembly to temperatures of varying ranges. These temperatures may be at or exceed 130 degrees Celsius, 160 degrees Celsius, 250 degrees Celsius, 350 degrees Celsius, or perhaps 400 degrees Celsius. The temperatures ranges tend to be application space specific depending on the process.

Next, for the embodiments, at 330, the carrier may be removed from the adhesive substrate. For some embodiments, the carrier may be UV transparent whereupon exposure to UV radiation, an adhesive strength of the second side of the adhesive substrate may be reduced to, or less than, approximately 0.1 N/mm as illustrated in FIG. 2e. For other embodiments, the adhesive strength may be reduced by application of thermal (IR) radiation. For an embodiment, after the reduction in adhesive strength has occurred, the carrier is removed from the substrate without use of solvent.

Next, for the embodiments, at 335, the adhesive substrate may be removed from the thinned work piece, as illustrated in FIG. 2g. For the embodiments, the removal of the adhesive substrate is to be accomplished without use of solvents. In an embodiment, the adhesive strength holding the adhesive substrate to the work piece may be reduced by application of UV radiation or thermal radiation. Regardless of how (or if) the adhesiveness is reduced, the adhesion is to be sufficiently low to allow peeling the adhesive substrate from the work piece without damaging any structures on the work piece. Additionally, for the embodiments, the adhesion is to be sufficiently low to allow peeling of the adhesive while leaving substantially no adhesive residue on the work piece, again without the use of solvents.

The operations described above with respect to the methods illustrated in FIG. 3 can be performed in a different order from those described herein in accordance with various embodiments. For example, it will be understood by those of ordinary skill that 335 could be carried out prior to 330. Additionally, 315 may be performed prior to 310. Moreover, as described earlier, not all work pieces require the support of a carrier; in this case, process 315 and 330 may be omitted for those embodiments.

The above-described choice of materials, geometry, number of layers, temperatures, reflow/thermal times, deposition, and assembly can all be varied by one of ordinary skill in the art to optimize the thermal performance of the adhesive substrate and the work piece, depending on the specific application, and selected operational and reliability characteristics.

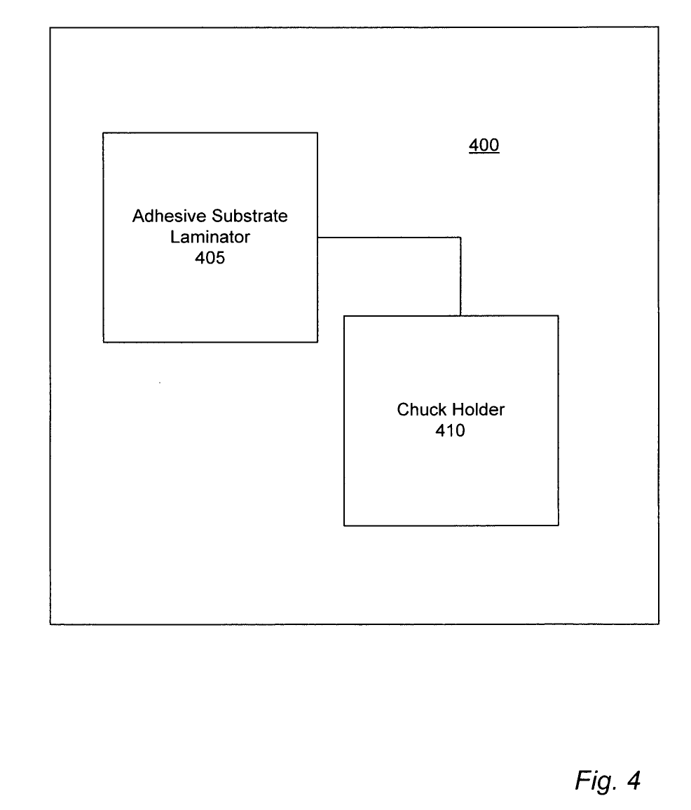

FIG. 4 illustrates a system 400 incorporating the adhesive substrate 130 of FIG. 1, in accordance with one embodiment of the invention. An adhesive substrate laminator 400 facilitates affixing of a carrier to a work piece using the adhesive substrate of FIG. 1 which has adhesive layers on first and second sides of the adhesive substrate. This may enable an exposed side of the work piece to be subjected to a thinning process and a post-thinning process that includes exposing the carrier, the work piece, and the adhesive substrate to a process temperature greater than 130 degrees Celsius. The adhesive substrate laminator may be a vacuum laminator for an embodiment.

The adhesive layers maintain adhesion of the carrier and the work piece to the adhesive substrate during the thinning process and the post-thinning. The system 400 further includes a chuck holder to receive and hold the thinned work piece affixed to the carrier by the adhesive substrate after the thinning process. This may enable dry removal of the carrier from the adhesive substrate, and the adhesive substrate from the work piece. In an embodiment, the chuck holder may be a vacuum chuck holder. Although specific embodiments have been illustrated and described herein, it will be appreciated by those of ordinary skill in the art, and others, that a wide variety of alternate and/or equivalent implementations may be substituted for the specific embodiment shown in the described without departing from the scope of the present invention. This application is intended to cover any adaptations or variations of the embodiment discussed herein. Therefore, it is manifested and intended that the invention be limited only by the claims and the equivalence thereof.

The embodiments of the invention in which an inclusive property are privilege is claimed or hereby defined as follows:

1. A substrate comprising:
a flexible film; and
an adhesive layer disposed on a side of the flexible film, said adhesive layer configured to maintain adhesion between the flexible film and a first side of a work piece during a process, during which the adhesive layer is exposed to one or more process operations subject to a process temperature greater than about 130 degrees Celsius, but releasable of the work piece without use of solvents.

2. The substrate of claim 1, wherein the process temperature is in a range of approximately 160 degrees Celsius to approximately 400 degrees Celsius.

3. The substrate of claim 1, wherein the flexible film comprises a glass transition temperature greater than approximately 160 degrees Celsius.

4. The substrate of claim 1, wherein the flexible film comprises a glass transition temperature greater than approximately 400 degrees Celsius.

5. The substrate of claim 1, wherein the adhesive layer is adapted to have less than about a 5% weight loss as determined by thermal gravimetric analysis (TGA) in a temperature range, of approximately 130 to approximately 400 degrees Celsius.

6. The substrate of claim 1, wherein the flexible film has an optical clarity sufficient to enable a user to observe fiducial marks on the first side of the work piece.

7. The substrate of claim 1, wherein the flexible film has a tensile strength greater than a force necessary to peel the adhesive substrate from the work piece.

8. The substrate of claim 1, wherein the flexible film comprises at least one material selected from the group consisting of at least a polyimide based material, a polynorborene based material, a liquid crystal polymer material, a polysolfone material, a polyethersulfone material, a polyether-ether-ketone material, a polysulfone material, a polyetherimide material, and a cyclo-olefin-polymer material.

9. The substrate of claim 1, wherein the adhesive layer has an adhesive strength to at least one of the following materials, a polyimide material, a metal pad, a bump material, and a SiO₂ material.

10. The substrate of claim 9, wherein the adhesive strength comprises an adhesive strength selected from the group consisting of an adhesive strength to the polyimide material equal to, or less than, approximately 1 g/mm² during a 180 degree peel; the adhesive strength to the metal pad and the bump material equal to, or less than, approximately 15 N/in during a 180 degree peel; and the adhesive strength to the SiO₂ material equal to or less than approximately 0.3 N/in during a 180 degree peel.

11. The substrate of claim 1, wherein the adhesive layer on the first side of the film comprises a thickness equal to or greater than structures on the first side of the work piece.

12. The substrate of claim 1, wherein the adhesive layer comprises a composition have at least one material selected from the group comprising silicon, polyimide, norborene, silicon elastomer based polymer, a polycyclic olefin polymer, a poly(ethylene carbonate), a poly(propylene carbonate), and other materials having similar properties.

13. The substrate of claim 1, wherein the adhesive layer is configured to have an adhesive strength to the work piece reduced to, or less than, approximately 0.1 N/mm after being exposed to radiation wherein the radiation is selected from the group consisting of UV radiation and thermal radiation.

14. The substrate of claim 1, wherein the work piece is selected from the group comprising a wafer and a carrier.

15. The substrate of claim 1, wherein the adhesive layer is a first adhesive layer and the substrate further comprises a second adhesive layer disposed on an opposite side of the flexible film, wherein the first and second adhesive layers are configured to:
affix a carrier to the work piece;
maintain adhesion between the carrier and the first side of the work piece during a thinning process of a second side of the work piece; and
maintain adhesion between the carrier and the first side of the work piece after the thinning process, during which the first and second adhesive layers are exposed to the one or more process operations.

16. A method comprising:
laminating a first side of an adhesive substrate to a first side of a work piece to create a work piece assembly;
processing the work piece assembly during which the work piece assembly including the adhesive substrate are subjected to a processing temperature in excess of 130 degrees Celsius while the adhesive substrate maintains adhesion with the work piece; and
removing the adhesive substrate from the processed work piece without using solvent.

17. The method of claim 16 wherein the processing of the work piece comprises depositing metal on a second side of the work piece assembly.

18. The method of claim 16, wherein the processing of the work piece comprises depositing a thin dielectric thin film on a second side of the work piece assembly.

19. The method of claim 16, wherein the processing of the work piece comprises electroplating a second side of the work piece assembly.

20. The method of claim 16, wherein the processing of the work piece comprises oxide deposition on a second side of the work piece assembly.

21. The method of claim 16, wherein the processing of the work piece comprises polymer deposition on a second side of the work piece assembly.

22. The method of claim 16, wherein the processing of the work piece comprises high temperature solder reflow of the work piece assembly.

23. The method of claim 16, wherein processing the work piece assembly while exposed to said processing temperature in excess of 130 degrees Celsius comprises exposing the work piece assembly to said processing temperature in a range of about 130 to about 500 degrees Celsius.

24. The method of claim 16, wherein processing the work piece assembly while exposed to said processing temperature in excess of 130 degrees Celsius comprises exposing the work piece assembly to said processing temperature in a range of about 160 to about 250 degrees Celsius.

25. The method of claim 16, wherein processing the work piece assembly while exposed to said processing temperature in excess of 130 degrees Celsius comprises exposing the work piece assembly to said processing temperature in a range of about 250 to about 400 degrees Celsius.

26. The method of claim 16, wherein creating the work piece assembly further comprises affixing a carrier to a second side of the adhesive substrate laminated to the work piece, and thinning a second side of the work piece prior to processing the work piece.

27. The method of claim 16, wherein the removing of the adhesive substrate comprises peeling the adhesive substrate from the processed work piece.

28. A system comprising:
a laminator to facilitate affixing of a carrier to a work piece using an adhesive substrate having adhesive layers on first and second sides of the adhesive substrate, to enable an exposed side of the work piece to be subjected to a thinning process and a post-thinning process that includes exposing the carrier, the work piece and the adhesive substrate to a process temperature greater than 130 degrees Celsius, the adhesive layers maintaining adhesion of the carrier and the work piece to the adhesive substrate during the thinning process and the post-thinning; and
a chuck holder to receive and hold the thinned work piece affixed to the carrier by the adhesive substrate after the thinning process, to allow dry removal of the carrier from the adhesive substrate, and the adhesive substrate from the work piece.

29. The system of claim 28, wherein the laminator comprises a vacuum laminator.

30. The system of claim 28, wherein the chuck holder comprises a vacuum chuck holder.
